(19) United States
(12) Patent Application Publication
(10) Pub. No.: US 2010/0009489 A1
(43) Pub. Date: Jan. 14, 2010

(54) METHOD AND SYSTEM FOR PRODUCING A SOLAR CELL USING ATMOSPHERIC PRESSURE PLASMA CHEMICAL VAPOR DEPOSITION

(76) Inventor: Chan Albert Tu, El Monte, CA (US)

Correspondence Address: MURABITO, HAO & BARNES, LLP, TWO NORTH MARKET STREET, THIRD FLOOR, SAN JOSE, CA, 95113, US

(21) Appl. No.: 12/499,590

(22) Filed: Jul. 8, 2009

Related U.S. Application Data
(60) Provisional application No. 61/079,021, filed on Jul. 8, 2008.

(51) Int. Cl. H01L 31/02; H01L 21/205; C23C 16/513

(52) U.S. Cl. 438/64; 438/478; 118/723 R; 257/E21.101; 257/E31.11

(57) ABSTRACT

A process and system for producing a thin-film solar cell using atmospheric pressure plasma chemical vapor deposition is disclosed. A plasma at substantially atmospheric pressure is used to deposit P-type layers, intrinsic layers and N-type layers to form one or more P-N junctions for use in a solar cell. The surface onto which a P-N junction is deposited may be prepared or cleaned using the plasma at substantially atmospheric pressure. Alternatively, the plasma at substantially atmospheric pressure may be used to deposit other layers of the solar cell such as conductive layers in contact with a P-N junction.

### RELATED APPLICATIONS

The present application claims the benefit of U.S. Provisional Patent Application No. 61/079,021, filed Jul. 8, 2008, entitled “ATMOSPHERIC PRESSURE PLASMA CHEMICAL VAPOR DEPOSITION (APP-CVD) FOR THIN FILM SOLAR CELL,” naming Chan Albert Tu as the inventor, and having attorney docket number NAPO-P001.PRO. That application is incorporated herein by reference in its entirety and for all purposes.

### BACKGROUND OF THE INVENTION

Conventional thin-film solar cells are currently used in many consumer applications to generate electricity from light energy. A P-N junction of the conventional solar cells is used to convert the light energy to electricity, where the P-N junction includes layers of P-type silicon and N-type silicon.

The P-N junction of conventional thin-film solar cells can be produced using a diffusion process. For example, an N-type silicon layer is diffused onto a P-type silicon wafer to form the P-N junction. However, diffusion is a time-consuming process and is relatively expensive. As such, the cost of conventional thin-film solar cells produced using diffusion is usually high.

Conventional thin-film solar cells may also be produced using chemical vapor deposition (CVD). More specifically, the layers of P-type silicon and N-type silicon of the P-N junction are deposited using a plasma under a very high vacuum in a vacuum chamber. The vacuum chamber and the associated equipment used to draw the high vacuum are very expensive, and therefore, the cost of conventional thin-film solar cells produced using CVD under high vacuum is typically high.

Additional equipment, separate from the equipment used to create the P-N junction, is also required to produce other components of the conventional thin-film solar cell. For example, prior to creation of the P-N junction, the substrate is typically cleaned on separate equipment. Additionally, after the P-N junction is applied to the substrate, additional layers are deposited using separate equipment. Since each piece of additional equipment is expensive, the cost of conventional thin-film solar cells is further increased.

### SUMMARY OF THE INVENTION

Accordingly, a need exists to produce a thin-film solar cell with reduced cost. More specifically, a need exists to produce a P-N junction and/or other components of a solar cell with reduced cost. Embodiments of the present invention provide novel solutions to these needs and others as described below.

Embodiments of the present invention are directed to a process and system for producing a thin-film solar cell using atmospheric pressure plasma chemical vapor deposition. More specifically, a plasma at substantially atmospheric pressure is used to deposit P-type layers, intrinsic layers and N-type layers to form one or more P-N junctions for use in a solar cell. The surface onto which a P-N junction is deposited may be prepared or cleaned using the plasma at substantially atmospheric pressure. Alternatively, the plasma at substantially atmospheric pressure may be used to deposit other layers of the solar cell such as conductive layers in contact with a P-N junction.

In this manner, the cost of producing a solar cell is reduced by using a plasma at substantially atmospheric pressure without an expensive vacuum chamber and associated equipment used to draw the vacuum. Additionally, by using the plasma at substantially atmospheric pressure to perform other functions related to production of the solar cell (e.g., prepare the surface onto which the P-N junction is deposited, deposit other layers of the solar cell, etc.) in lieu of other more expensive equipment, the cost of producing a solar cell may be further reduced.

In one embodiment, a process for atmospheric pressure plasma chemical vapor deposition includes introducing a first gas into a chamber. A plasma is ignited inside the chamber using the first gas, wherein the igniting further includes igniting the plasma at conditions including substantially atmospheric pressure. A second gas is introduced into the chamber, wherein the second gas includes a constituent, and wherein the introducing the second gas further includes introducing the second gas into the plasma along with the first gas into the chamber. A first layer is deposited on an object within the chamber, wherein the first layer includes the constituent, and wherein the depositing further includes depositing the first layer using the plasma at substantially atmospheric pressure.

In another embodiment, a process of producing a solar cell using atmospheric pressure plasma chemical vapor deposition includes accessing an object including a substrate with a first conductive layer disposed thereon. A plurality of layers are deposited on the object to form a P-N junction, wherein the depositing further includes depositing the plurality of layers using at least one plasma ignited within at least one chamber at substantially atmospheric pressure, and wherein the plurality of layers include a P-type layer, an N-type layer, and an intrinsic layer disposed between the P-type layer and the N-type layer. A second conductive layer is disposed on the plurality of layers to form the solar cell, and wherein the plurality of layers are operable to generate a potential difference between the first conductive layer and the second conductive layer when exposed to light energy.

In yet another embodiment, a system for producing a solar cell using atmospheric pressure plasma chemical vapor deposition includes a plurality of plasma heads. A first plasma head includes a first chamber, wherein the first plasma head is operable to deposit a P-type layer using a first plasma ignited within the first chamber at substantially atmospheric pressure. A second plasma head is coupled with the first plasma head and includes a second chamber, wherein the second plasma head is operable to deposit an intrinsic layer using a second plasma ignited within the second chamber at substantially atmospheric pressure. A third plasma head is coupled with the second plasma head and includes a third chamber, wherein the third plasma head is operable to deposit a N-type layer using a third plasma ignited within the third chamber at substantially atmospheric pressure. The system also includes a component for moving an object to enable the plurality of plasma heads to deposit a plurality of layers on the object, wherein the object includes a substrate with a first conductive layer disposed thereon, wherein the plurality of layers include a P-type layer, an N-type layer, and an intrinsic layer disposed between the P-type layer and the N-type layer, and wherein the plurality of layers are operable to generate a potential difference between the first conductive layer and a second conductive layer when exposed to light.

### BRIEF DESCRIPTION OF THE DRAWINGS

The present invention is illustrated by way of example, and not by way of limitation, in the figures of the accompanying drawings and in which like reference numerals refer to similar elements.

FIG. 1 shows a flowchart of an exemplary process for atmospheric pressure plasma chemical vapor deposition in accordance with one embodiment of the present invention.

FIG. 2 shows an exemplary plasma head for performing atmospheric pressure plasma chemical vapor deposition to deposit a layer on a surface which is between two electrodes in accordance with one embodiment of the present invention.

FIG. 3 shows an exemplary plasma head for performing atmospheric pressure plasma chemical vapor deposition to deposit a layer on a surface which is not between two electrodes in accordance with one embodiment of the present invention.

FIG. 4 shows an exemplary thin-film solar cell with a single P-N junction in accordance with one embodiment of the present invention.

FIG. 5 shows an exemplary thin-film solar cell with a single P-N junction and a second substrate in accordance with one embodiment of the present invention.

FIG. 6 shows an exemplary thin-film solar cell with multiple P-N junctions in accordance with one embodiment of the present invention.

FIG. 7 shows an exemplary thin-film solar cell with multiple P-N junctions and a second substrate in accordance with one embodiment of the present invention.

FIG. 8 shows a flowchart of an exemplary process for producing a thin-film solar cell using atmospheric pressure plasma chemical vapor deposition in accordance with one embodiment of the present invention.

FIG. 9 shows an exemplary system for producing a thin-film solar cell using atmospheric pressure plasma chemical vapor deposition in accordance with one embodiment of the present invention.

FIG. 10 shows an exemplary flow of gas through a system in accordance with one embodiment of the present invention.

FIG. 11 shows a flowchart of an exemplary process for producing a Silicon gas in accordance with one embodiment of the present invention.

### DETAILED DESCRIPTION OF THE INVENTION

Reference will now be made in detail to embodiments of the present invention, examples of which are illustrated in the accompanying drawings. While the present invention will be discussed in conjunction with the following embodiments, it will be understood that they are not intended to limit the present invention to these embodiments alone. On the contrary, the present invention is intended to cover alternatives, modifications, and equivalents which may be included with the spirit and scope of the present invention as defined by the appended claims. Furthermore, in the following detailed description of the present invention, numerous specific details are set forth in order to provide a thorough understanding of the present invention. However, embodiments of the present invention may be practiced without these specific details. In other instances, well-known methods, procedures, components, and circuits have not been described in detail so as not to unnecessarily obscure aspects of the present invention.

### Embodiments of the Invention

Embodiments of the present invention are directed to a method and system for producing a solar cell (e.g., a thin-film solar cell) using atmospheric pressure plasma chemical vapor deposition (APP-CVD). “APP-CVD” as used herein may be any form of chemical vapor deposition using a plasma within a chamber which is at approximately atmospheric pressure or a pressure greater than atmospheric pressure. The term “substantially atmospheric pressure” as used herein may be a pressure approximately equal to atmospheric pressure or a pressure greater than atmospheric pressure.

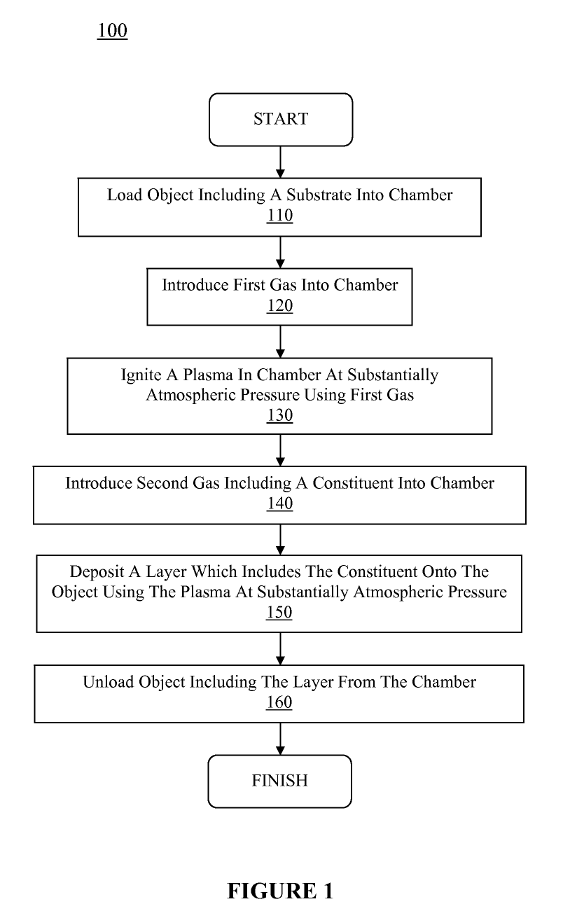

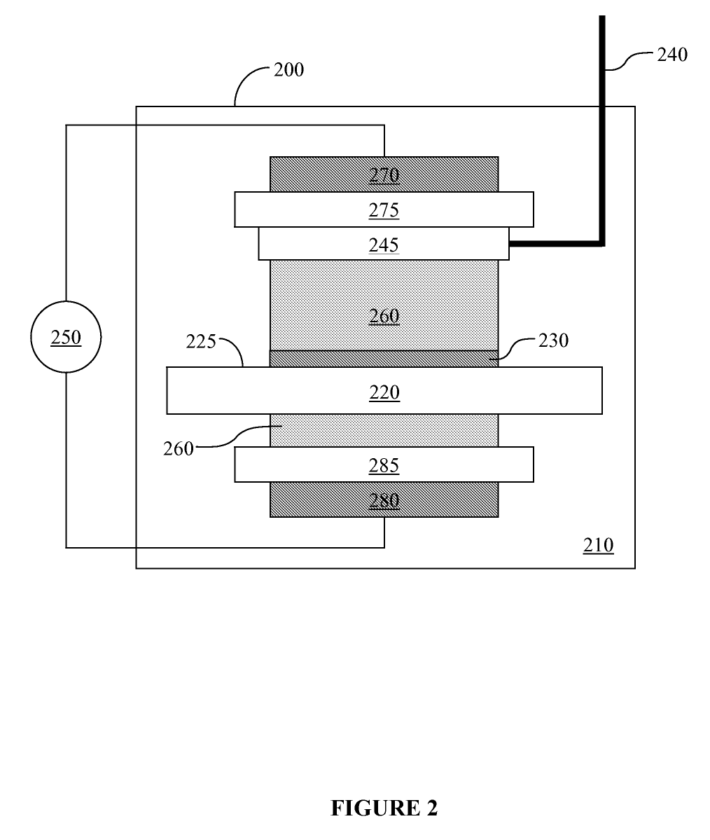

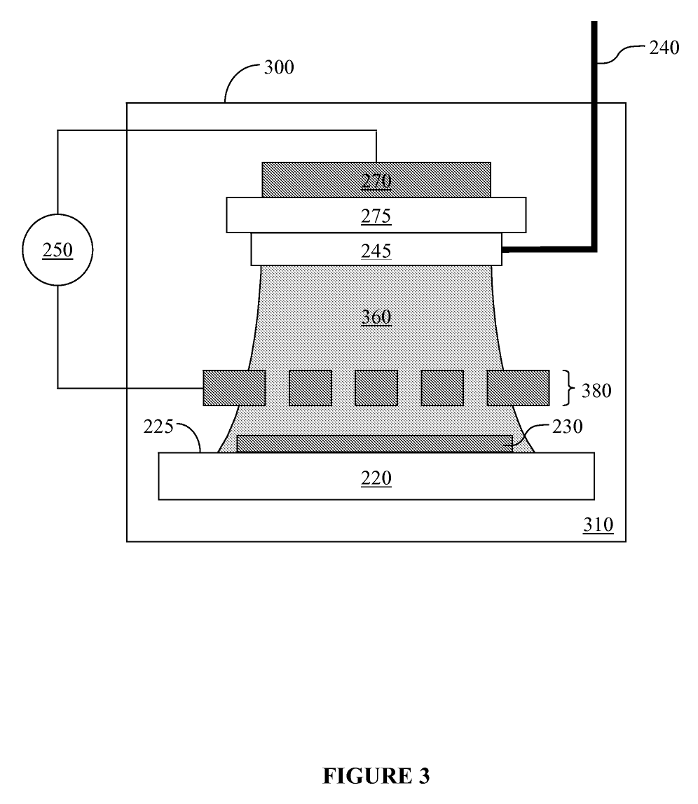

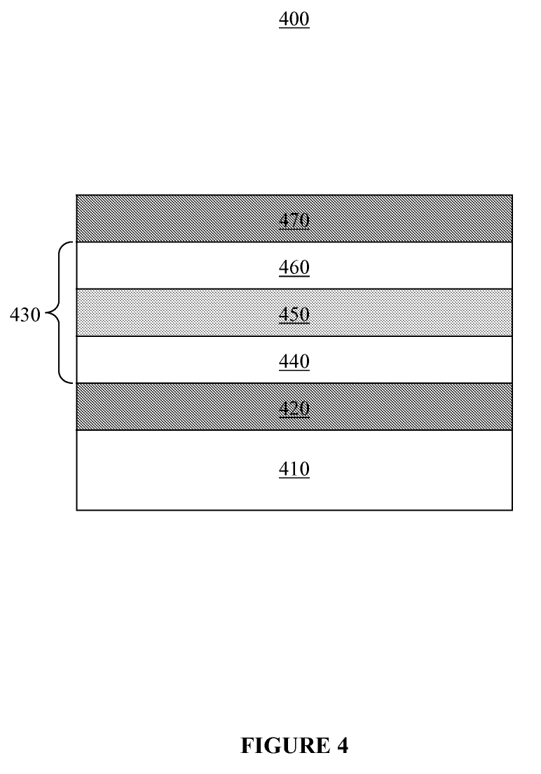

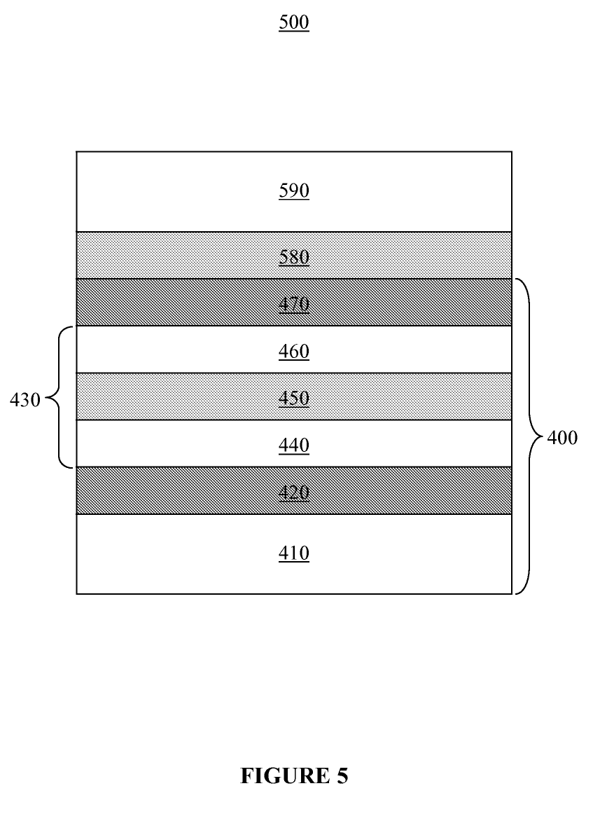

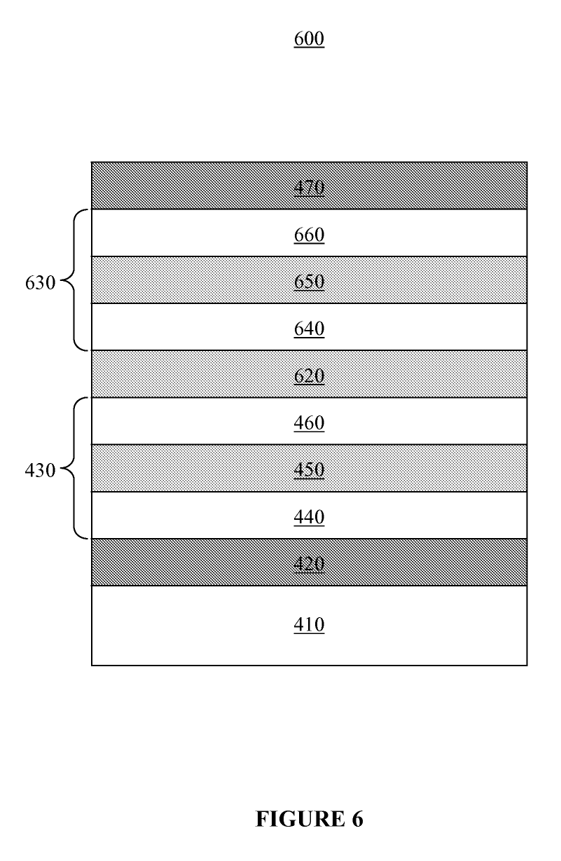

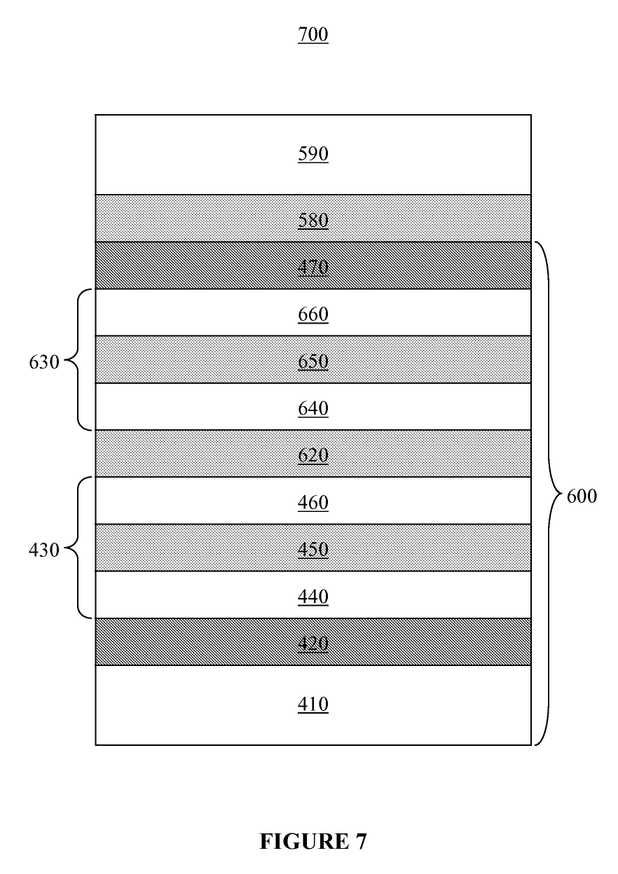

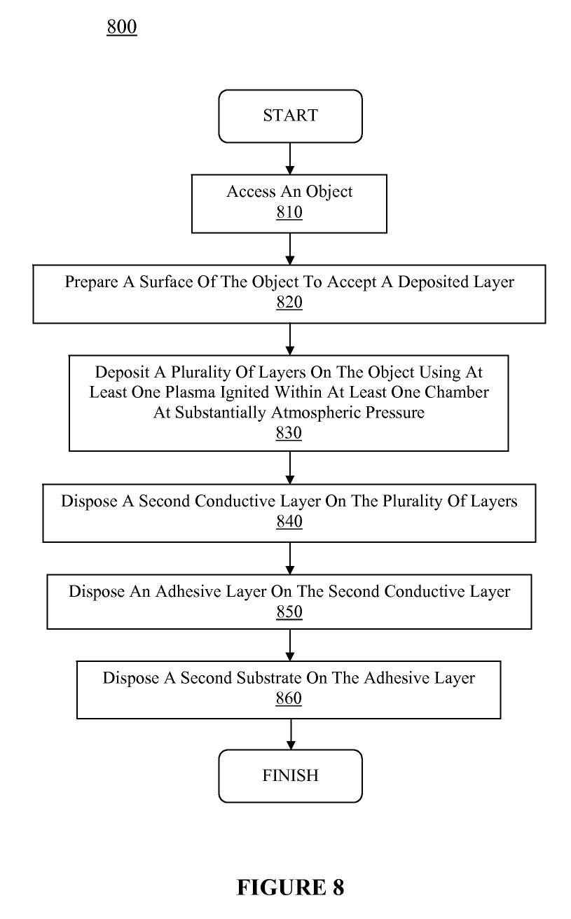

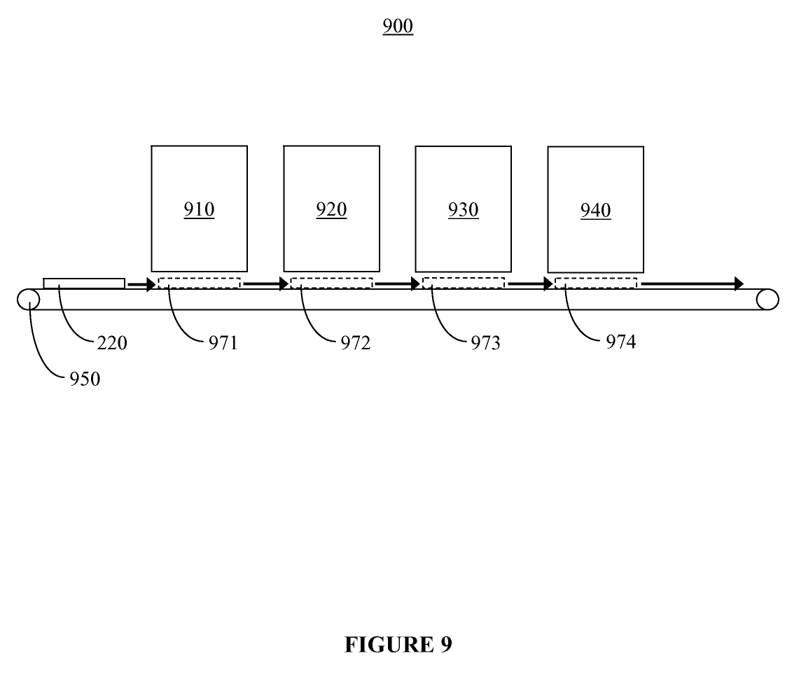

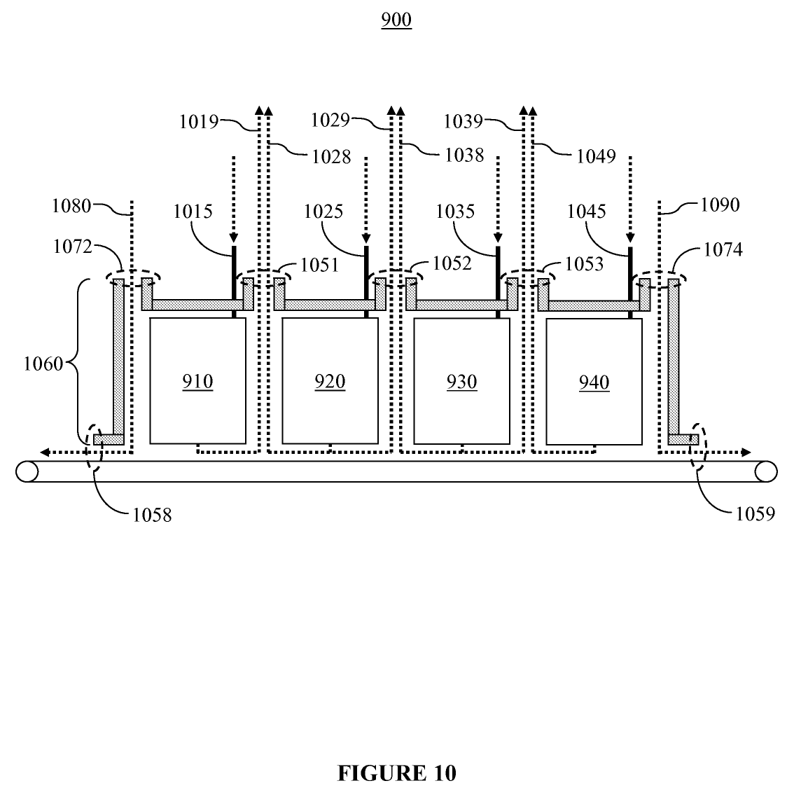

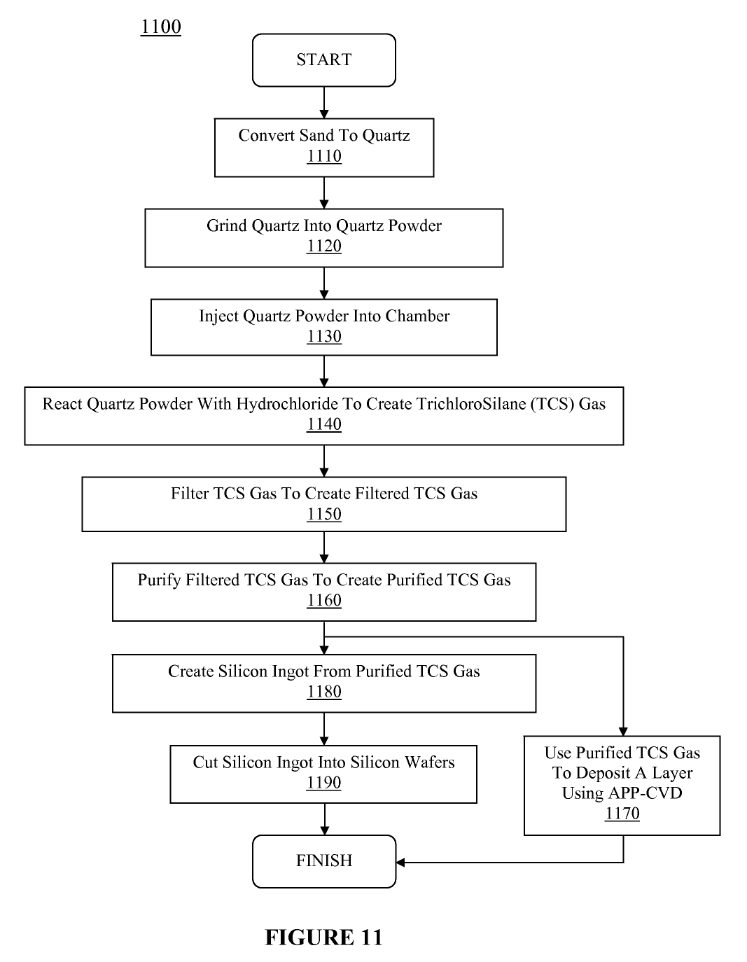

An APP-CVD process (e.g., process 100 of FIG. 1, process 800 of FIG. 8, etc.) may be used to deposit one or more layers of a solar cell or thin-film solar cell (e.g., P-type layers, intrinsic layers, N-type layers, conductive layers, tunnel junction layers, some combination thereof, etc.). A plasma head (e.g., plasma head 200 of FIG. 2, plasma head 300 of FIG. 3, etc.) may be used to deposit one or more of the layers of the solar cell (e.g., solar cell 400 of FIG. 4, solar cell 500 of FIG. 5, solar cell 600 of FIG. 6, solar cell 700 of FIG. 7, etc.). A plurality of plasma heads may be integrated into a single system (e.g., system 900 of FIGS. 9 and 10), where each of the plurality of plasma heads may be used to perform a different function (e.g., prepare or clean a surface, deposit a first layer, deposit a second layer, etc.) using APP-CVD. Additionally, a process (e.g., process 1100 of FIG. 11) may be used to produce a gas including a Silicon component which in turn may be used to deposit a layer using APP-CVD and/or create silicon wafers (e.g., for use as solar cell substrates).

### Atmospheric Pressure Plasma Chemical Vapor Deposition

FIG. 1 shows a flowchart of exemplary process 100 for APP-CVD in accordance with one embodiment of the present invention. FIG. 1 will be described in conjunction with FIGS. 2 and 3. FIG. 2 shows exemplary plasma head 200 for performing APP-CVD to deposit a layer on a surface which is between two electrodes in accordance with one embodiment of the present invention, whereas FIG. 3 shows exemplary plasma head 300 for performing APP-CVD to deposit a layer on a surface which is not between two electrodes in accordance with one embodiment of the present invention.

As shown in FIG. 1, step 110 involves loading an object including a substrate into a chamber. For example, object 220 may be loaded into a chamber (e.g., chamber 210 of FIG. 2, chamber 310 of FIG. 3, etc.) of a plasma head (e.g., plasma head 200 of FIG. 2, plasma head 300 of FIG. 3, etc.). The object (e.g., 220) may be a substrate only (e.g., without any additional layers) or a substrate with at least one additional layer (e.g., a P-type silicon layer, an intrinsic layer, a N-type silicon layer, a conductive layer, a tunnel junction layer, etc.). The object (e.g., 220) may include one or more layers of a solar cell (e.g., solar cell 400 of FIG. 4, solar cell 500 of FIG. 5, solar cell 600 of FIG. 6, solar cell 700 of FIG. 7, etc.). The object (e.g., 220) may be loaded into the chamber (e.g., 210, 310, etc.) either manually (e.g., placed in the chamber by a person) or automatically (e.g., carried into the chamber by a conveyor belt, robot arm, other component capable of moving objects, etc.).

Step 120 involves introducing a first gas into the chamber. The first gas may include a noble gas (e.g., argon, helium, nitrogen, some combination thereof, etc.) in one embodiment. The first gas may include another gas (e.g., Hydrogen) in one embodiment. Additionally, the first gas may be introduced into the chamber (e.g., 210, 310, etc.) via a gas line (e.g., 240) which directs the gas to a component (e.g., 245) for releasing the gas into the chamber. The component for releasing the gas (e.g., 245) may be a nozzle, multiple nozzles, at least one hole, a shower head, etc.

As shown in FIG. 1, step 130 involves igniting a plasma in the chamber at substantially atmospheric pressure using the first gas. The plasma (e.g., 260 of FIG. 2, 360 of FIG. 3, etc.) may be ignited by applying a voltage (e.g., 250) between two electrodes (e.g., electrode 270 and 280 of FIG. 2, electrodes 270 and 380 of FIG. 3, etc.). In one embodiment, the voltage (e.g., 250) may be approximately 1 kV or greater.

The pressure within the chamber (e.g., 210, 310, etc.) may be approximately equal to atmospheric pressure while the plasma (e.g., 260, 360, etc.) is ignited in step 130. Alternatively, the pressure within the chamber (e.g., 210, 310, etc.) may be greater than atmospheric pressure while the plasma (e.g., 260, 360, etc.) is ignited, thereby reducing the ability of contaminants (e.g., air, other gases, dirt or undesirable particulate matter, etc.) to enter the chamber.

The plasma ignited in step 130 remains between the electrodes in one embodiment. For example, plasma 260 remains between electrodes 270 and 280 as shown in FIG. 2. Accordingly, an object (e.g., 220) may be passed between the electrodes (e.g., 270 and 280) into the plasma to deposit a layer (e.g., 230) on a surface (e.g., 225) of the object (e.g., as discussed below with respect to step 150).

Alternatively, the plasma ignited in step 130 may extend beyond one or more of the electrodes in one embodiment. For example, plasma 360 extends beyond electrode 380 (e.g., goes through holes in electrode 360) as shown in FIG. 3. Accordingly, an object (e.g., 220) may be passed outside of the electrodes (e.g., 270 and 380) into the plasma to deposit a layer (e.g., 230) on a surface (e.g., 225) of the object (e.g., as discussed below with respect to step 150).

One of more of the electrodes used to create the plasma (e.g., ignited in step 130) may be protected by a layer of ceramic. For example, electrode 270 may be protected by ceramic layer 275 and electrode 280 may be protected by ceramic layer 285. Alternatively, one or more of the electrodes may include or otherwise be integrated with a ceramic protective layer. For example, electrode 380 may be a ceramic electrode in one embodiment.

As shown in FIG. 1, step 140 involves introducing a second gas including a constituent into the chamber, while step 150 involves depositing a layer which includes the constituent (e.g., layer 230) onto the object (e.g., surface 225 of object 220) using the plasma at substantially atmospheric pressure. The constituent of the second gas may be a component used to make a layer of a solar cell (e.g., a P-type silicon layer, an intrinsic layer, a N-type silicon layer, a conductive layer, a tunnel junction layer, etc.). For example, where the second gas comprises a mixture of a processing gas (e.g., a gas which includes a Silicon component such as Silane, Dichlorosilane, Trichlorosilane, Tetrachlorosilane, a gas which includes a Germanium component, etc.) and a dopant such as Diborane, the layer deposited in step 150 may be a P-type silicon layer. Where the second gas comprises a mixture of a processing gas and a dopant such as Phosphine, the layer deposited in step 150 may be an N-type silicon layer. And where the second gas is a processing gas without a dopant, the layer deposited in step 150 may be an intrinsic layer.

In one embodiment, the layer (e.g., 230) deposited in step 150 may be a conductive layer (e.g., a transparent conductive layer, a transparent contact layer, etc.). In one embodiment, the second gas introduced in step 140 may be a mixture of Diethylzinc, Oxygen and a gas which includes aluminum (e.g., Diethylaluminum, Trimethylaluminum, etc.).

It should be appreciated that the object (e.g., 220) may be moved through the chamber (e.g., 210, 310, etc.) while the layer is deposited in step 150 in one embodiment. Alternatively, the object (e.g., 220) may remain stationary in the chamber (e.g., 210, 310, etc.) while the layer is deposited in step 150.

Further, the second gas may be introduced into the chamber (e.g., 210, 310, etc.) using a gas line (e.g., 240) and component for releasing the gas (e.g., 245). In one embodiment, the second gas may be introduced into the chamber in step 140 contemporaneously with the first gas. In this manner, the first gas may act as a carrier gas for the second gas introduced in step 140.

As shown in FIG. 1, step 160 of process 100 involves unloading the object including the layer (e.g., deposited in step 150) from the chamber. The object (e.g., 220) may be unloaded from the chamber (e.g., 210, 310, etc.) either manually (e.g., removed from the chamber by a person) or automatically (e.g., carried from the chamber by a conveyor belt, robot arm, other component capable of moving objects, etc.).

### Solar Cells Produced Using Atmospheric Pressure Plasma Chemical Vapor Deposition

FIG. 4 shows exemplary thin-film solar cell 400 with a single P-N junction in accordance with one embodiment of the present invention. As shown in FIG. 4, solar cell 400 includes first conductive layer 420 disposed on substrate 410. P-N junction 430 is disposed on first conductive layer 420, where P-N junction 430 includes P-type silicon layer 440 disposed on first conductive layer 420, intrinsic layer 450 disposed on P-type silicon layer 440, and N-type silicon layer 460 disposed on intrinsic layer 450. Solar cell 400 also includes second conductive layer 470 disposed on N-type silicon layer 460. In this manner, a potential difference between first conductive layer 420 and second conductive layer 470 may be generated when solar cell 400 is exposed to light energy (e.g., sunlight, other light, etc.). Additionally, in one embodiment, solar cell 400 may be a photovoltaic solar cell.

In one embodiment, one or more layers of P-N junction 430 (e.g., 440, 450, 460, some combination thereof, etc.) may be deposited using APP-CVD (e.g., in step 150 of FIG. 1). For example, P-type silicon layer 440 may be deposited using Argon and Hydrogen as the first gas (e.g., introduced in step 120 of FIG. 1) and a mixture of a processing gas (e.g., a gas which includes a Silicon component such as Silane, Dichlorosilane, Trichlorosilane, Tetrachlorosilane, a gas which includes a Germanium component, etc.) and Diborane (e.g., as a dopant) as the second gas (e.g., introduced in step 140 of FIG. 1). In one embodiment, intrinsic layer 450 may be deposited using Argon and Hydrogen as the first gas (e.g., the first gas introduced in step 120 of FIG. 1) and a processing gas (e.g., a gas which includes a Silicon component such as Silane, Dichlorosilane, Trichlorosilane, Tetrachlorosilane, a gas which includes a Germanium component, etc.) without a dopant as the second gas (e.g., introduced in step 140 of FIG. 1). In another embodiment, N-type silicon layer 460 may be deposited using Argon and Hydrogen as the first gas (e.g., introduced in step 120 of FIG. 1) and a mixture of a processing gas (e.g., a gas which includes a Silicon component such as Silane, Dichlorosilane, Trichlorosilane, Tetrachlorosilane, a gas which includes a Germanium component, etc.) and Phosphine (e.g., as a dopant) as the second gas (e.g., introduced in step 140 of FIG. 1).

As shown in FIG. 4, first conductive layer 420 and/or second conductive layer 470 may be deposited using APP-CVD (e.g., in step 150 of FIG. 1). For example, first conductive layer 420 and/or second conductive layer 470 may be deposited using Argon and Nitrogen as the first gas (e.g., introduced in step 120 of FIG. 1) and a mixture of Diethylzinc, Oxygen and a gas which includes aluminum (e.g., Diethylaluminum, Trimethylaluminum, etc.) as the second gas (e.g., introduced in step 140 of FIG. 1). And in one embodiment, first conductive layer 420 and/or second conductive layer 470 may be a transparent conductive layer or transparent contact layer.

In one embodiment, first conductive layer 420 and/or second conductive layer 470 may include Aluminum and/or Silver. Alternatively, first conductive layer 420 and/or second conductive layer 470 may include Indium Tin Oxide (ITO). And in one embodiment, first conductive layer 420 and/or second conductive layer 470 may be applied using a process other than APP-CVD such as screen printing, sputtering, thermal evaporation, etc.

Solar cell 400 may be used in such applications as residential, commercial, automotive, and as one of a plurality of solar cells forming a solar power plant. In one embodiment, conductive layers 420 and 470 may be transparent, and therefore, solar cell 400 may be substantially transparent. As such, solar cell 400 may be used to cover windows (e.g., of residential buildings, commercial buildings, automobiles, etc.), to tint windows (e.g., of residential buildings, commercial buildings, automobiles, etc.), etc. As such, in one embodiment, solar cell 400 may be a photovoltaic solar cell window.

Substrate 410 may comprise silicon, glass, polymer, steel (e.g., stainless steel, etc.), or some combination thereof. Substrate 410 may be rigid and formed in any shape (e.g., flat, bent, curved, etc.). Alternatively, substrate 410 may be flexible, and therefore, may be bent or formed after manufacturing (e.g., making it suitable for window covering or tinting, etc.).

Although FIG. 4 shows a specific number of layers, it should be appreciated that solar cell 400 may include a larger or smaller number of layers in other embodiments. It should also be appreciated that the layers of solar cell 400 are not to scale, and therefore, may be different sizes, thicknesses, etc. Further, although FIG. 4 shows a specific ordering of layers, it should be appreciated that solar cell 400 may have a different ordering of layers in other embodiments. For example, P-type silicon layer 440 may be switched with N-type silicon layer 460 in one embodiment.

FIG. 5 shows exemplary thin-film solar cell 500 with a single P-N junction and a second substrate in accordance with one embodiment of the present invention. As shown in FIG. 5, solar cell 500 is similar to solar cell 400 with the addition of adhesive layer 580 and second substrate 590. As shown in FIG. 5, adhesive layer 580 is disposed on second conductive layer 470, while second substrate 590 is disposed on adhesive layer 580. In one embodiment, adhesive layer 580 may be used to adhere second substrate 590 to solar cell 400 (e.g., second conductive layer 470). In this manner, a potential difference between first conductive layer 420 and second conductive layer 470 may be generated when solar cell 500 is exposed to light (e.g., sunlight, other light, etc.). Additionally, in one embodiment, solar cell 500 may be a photovoltaic solar cell.

Adhesive layer 580 may include a polymer such as polyethylenevinylacetate (PEVA) in one embodiment. Adhesive layer 580 may be transparent in one embodiment. Additionally, adhesive layer 580 may be applied via APP-CVD (e.g., in step 150 of FIG. 1), a thermal process (e.g., applying a sheet of the adhesive and melting it, etc.), etc.

Second substrate 590 may comprise silicon, glass, polymer, steel (e.g., stainless steel, etc.), or some combination thereof. Substrate 590 may be rigid and formed in any shape (e.g., flat, bent, curved, etc.). Alternatively, substrate 590 may be flexible, and therefore, may be bent or formed after manufacturing (e.g., making it suitable for window covering or tinting, etc.).

Solar cell 500 may be used in applications similar to that of solar cell 400 described herein. As such, in one embodiment, solar cell 500 may be a photovoltaic solar cell window. Additionally, solar cell 500 may be substantially transparent in one embodiment.

Although FIG. 5 shows a specific number of layers, it should be appreciated that solar cell 500 may include a larger or smaller number of layers in other embodiments. It should also be appreciated that the layers of solar cell 500 are not to scale, and therefore, may be different sizes, thicknesses, etc. Further, although FIG. 5 shows a specific ordering of layers, it should be appreciated that solar cell 500 may have a different ordering of layers in other embodiments. For example, P-type silicon layer 440 may be switched with N-type silicon layer 460 in one embodiment.

FIG. 6 shows exemplary thin-film solar cell 600 with multiple P-N junctions in accordance with one embodiment of the present invention. As shown in FIG. 6, solar cell 600 is similar to solar cell 400, except that solar cell 600 has multiple P-N junctions (e.g., 430 and 630). More specifically, P-N junction 630 is disposed between tunnel junction layer 620 and second conductive layer 470, where tunnel junction layer 620 is disposed on N-type layer 460. P-N junction 630 includes P-type silicon layer 640 disposed on tunnel junction layer 620, intrinsic layer 650 disposed on P-type silicon layer 640, and N-type silicon layer 660 disposed on intrinsic layer 650. In this manner, a potential difference between first conductive layer 420 and second conductive layer 470 may be generated when solar cell 600 is exposed to light (e.g., sunlight, other light, etc.). Additionally, in one embodiment, solar cell 600 may be a photovoltaic solar cell.

In one embodiment, one or more layers of P-N junction 630 (e.g., 640, 650, 660, some combination thereof, etc.) may be deposited using APP-CVD (e.g., in step 150 of FIG. 1). For example, P-type silicon layer 640 may be deposited using Argon and Hydrogen as the first gas (e.g., introduced in step 120 of FIG. 1) and a mixture of a processing gas (e.g., a gas which includes a Silicon component such as Silane, Dichlorosilane, Trichlorosilane, Tetrachlorosilane, a gas which includes a Germanium component, etc.) and Diborane (e.g., as a dopant) as the second gas (e.g., introduced in step 140 of FIG. 1). In one embodiment, intrinsic layer 650 may be deposited using Argon and Hydrogen as the first gas (e.g., the first gas introduced in step 120 of FIG. 1) and a processing gas (e.g., a gas which includes a Silicon component such as Silane, Dichlorosilane, Trichlorosilane, Tetrachlorosilane, a gas which includes a Germanium component, etc.) without a dopant as the second gas (e.g., introduced in step 140 of FIG. 1). In another embodiment, N-type silicon layer 660 may be deposited using Argon and Hydrogen as the first gas (e.g., introduced in step 120 of FIG. 1) and a mixture of a processing gas (e.g., a gas which includes a Silicon component such as Silane, Dichlorosilane, Trichlorosilane, Tetrachlorosilane, a gas which includes a Germanium component, etc.) and Phosphine (e.g., as a dopant) as the second gas (e.g., introduced in step 140 of FIG. 1).

Tunnel junction layer 620 may be deposited using APP-CVD (e.g., in step 150 of FIG. 1) in one embodiment. For example, tunnel junction layer 620 may be deposited using Argon and Hydrogen as the first gas (e.g., introduced in step 120 of FIG. 1) and a processing gas (e.g., a gas which includes a Silicon component such as Silane, Dichlorosilane, Trichlorosilane, Tetrachlorosilane, a gas which includes a Germanium component, etc.) without a dopant as the second gas (e.g., introduced in step 140 of FIG. 1). Alternatively, tunnel junction layer 620 may be disposed using screen printing, sputtering, Electron beam evaporation, thermal evaporation, etc.

Solar cell 600 may be used in applications similar to that of solar cell 400 described herein. As such, in one embodiment, solar cell 600 may be a photovoltaic solar cell window. Additionally, solar cell 600 may be substantially transparent in one embodiment.

In one embodiment, the P-N junctions of solar cell 600 may be arranged in order in decreasing band gap to decrease the amount of energy lost during absorption and consequently increase the efficiency of solar cell 600. For example, the band gap of P-N junction 630 may be larger than the band gap of P-N junction 430, thereby improving efficiency of solar cell 600 when light shines downward (e.g., striking P-N junction 630 before P-N junction 430) onto solar cell 600.

Although FIG. 6 shows a specific number of layers, it should be appreciated that solar cell 600 may include a larger or smaller number of layers in other embodiments. It should also be appreciated that the layers of solar cell 600 are not to scale, and therefore, may be different sizes, thicknesses, etc. Further, although FIG. 6 shows a specific ordering of layers, it should be appreciated that solar cell 600 may have a different ordering of layers in other embodiments. For example, P-type silicon layer 440 may be switched with N-type silicon layer 460 in one embodiment. As another example, P-type silicon layer 640 may be switched with N-type silicon layer 660 in one embodiment.

FIG. 7 shows exemplary thin-film solar cell 700 with multiple P-N junctions and a second substrate in accordance with one embodiment of the present invention. As shown in FIG. 7, solar cell 700 is similar to solar cell 600 with the addition of adhesive layer 580 and second substrate 590. As shown in FIG. 7, adhesive layer 580 is disposed on second conductive layer 470, while second substrate 590 is disposed on adhesive layer 580. In one embodiment, adhesive layer 580 may be used to adhere second substrate 590 to solar cell 600 (e.g., second conductive layer 470). In this manner, a potential difference between first conductive layer 420 and second conductive layer 470 may be generated when solar cell 700 is exposed to light (e.g., sunlight, other light, etc.). Additionally, in one embodiment, solar cell 700 may be a photovoltaic solar cell.

Solar cell 700 may be used in applications similar to that of solar cell 400 described herein. As such, in one embodiment, solar cell 700 may be a photovoltaic solar cell window. Additionally, solar cell 700 may be substantially transparent in one embodiment.

Although FIG. 7 shows a specific number of layers, it should be appreciated that solar cell 700 may include a larger or smaller number of layers in other embodiments. It should also be appreciated that the layers of solar cell 700 are not to scale, and therefore, may be different sizes, thicknesses, etc. Further, although FIG. 7 shows a specific ordering of layers, it should be appreciated that solar cell 700 may have a different ordering of layers in other embodiments. For example, P-type silicon layer 440 may be switched with N-type silicon layer 460 in one embodiment. As another example, P-type silicon layer 640 may be switched with N-type silicon layer 660 in one embodiment.

### System for Producing Solar Cells Produced Using Atmospheric Pressure Plasma Chemical Vapor Deposition

FIG. 8 shows a flowchart of exemplary process 800 for producing a thin-film solar cell using APP-CVD in accordance with another embodiment of the present invention. FIG. 8 will be described in conjunction with FIG. 9 which shows exemplary system 900 for producing a solar cell using APP-CVD in accordance with one embodiment of the present invention.

As shown in FIG. 8, step 810 involves accessing an object. For example, object 220 may be accessed, where object 220 may include a substrate (e.g., 410) in one embodiment. Alternatively, object 220 may include a substrate (e.g., 410) and at least one other layer (e.g., a conductive layer such as first conductive layer 420, a layer of a P-N junction such as P-type silicon layer 440, etc.).

Step 820 involves preparing a surface (e.g., 225) of the object to accept a deposited layer. The surface may be prepared or cleaned, in one embodiment, using a plasma ignited at substantially atmospheric pressure. For example, the object (e.g., 220) may be placed in a chamber (e.g., 210, 310, etc.) of a plasma head (e.g., 200, 300, etc.), a gas (e.g., Hydrogen) may be introduced into the chamber, and the plasma may be ignited within the chamber at substantially atmospheric pressure using the gas to prepare or clean the object.

As shown in FIG. 8, step 830 involves depositing a plurality of layers on the object, to form at least one P-N junction, using at least one plasma ignited within at least one chamber at substantially atmospheric pressure. Each of the layers deposited in step 830 may be deposited using APP-CVD (e.g., in step 150 of FIG. 1) in one embodiment. The layers deposited in step 830 may form one P-N junction (e.g., 430) or multiple P-N junctions (e.g., 430 and 630) in one embodiment. In this manner, the layers deposited in step 830 may include at least one P-type silicon layer (e.g., 440, 640, etc.), at least one intrinsic layer (e.g., 450, 650, etc.), at least one N-type silicon layer (e.g., 460, 660, etc.), some combination thereof, etc. Alternatively, the layers deposited in step 830 may form at least one conductive layer (e.g., 420, 470, etc.). And in one embodiment, the layers deposited in step 830 may form at least one tunnel junction layer (e.g., 620).

In one embodiment, the layers deposited in step 830 may be deposited using a single plasma head (e.g., 200, 300, etc.). The single plasma head used to deposit the layers in step 830 may be the same plasma head used to prepare the object in step 820 or may be a different plasma head from that used to prepare the object in step 820.

Alternatively, the layers deposited in step 830 may be deposited using more than one plasma head (e.g., 200, 300, etc.) as discussed herein with respect to FIG. 9. The multiple plasma heads may include the plasma head used to prepare the object in step 820 or may be different plasma heads from that used to prepare the object in step 820.

Step 840 involves disposing a second conductive layer on the plurality of layers (e.g., deposited in step 830). The second conductive layer (e.g., 470) may be deposited using APP-CVD (e.g., in step 150 of FIG. 1). Alternatively, second conductive layer (e.g., 470) may be disposed using another method (e.g., screen printing, sputtering, Electron beam evaporation, thermal evaporation, etc.).

As shown in FIG. 8, step 850 involves disposing an adhesive layer (e.g., 580) on the second conductive layer (e.g., 470). The adhesive layer (e.g., 580) may include a polymer such as polyethylenevinylacetate (PEVA) in one embodiment. The adhesive layer (e.g., 580) may be transparent in one embodiment. Additionally, the adhesive layer (e.g., 580) may be applied in step 850 via APP-CVD (e.g., in step 150 of FIG. 1), a thermal process (e.g., applying a sheet of the adhesive and melting it, etc.), etc.

Step 860 involves disposing a second substrate (e.g., 590) on the adhesive layer (e.g., 580). In one embodiment, the adhesive layer (e.g., 580) may be used to adhere the second substrate (e.g., 590) to the solar cell (e.g., 400, 500, 600, 700, etc.) and/or the second conductive layer (e.g., 470, that disposed in step 840, etc.).

### System for Producing Solar Cells Produced Using Atmospheric Pressure Plasma Chemical Vapor Deposition

FIG. 9 shows exemplary system 900 for producing a thin-film solar cell using APP-CVD in accordance with one embodiment of the present invention. As shown in FIG. 9, system 900 includes multiple plasma heads (e.g., 910, 920, 930 and 940) which may operate or otherwise be configured similarly to plasma head 200 of FIG. 2 or plasma head 300 of FIG. 3. System 900 also includes component 950 for moving an object (e.g., 220) to enable the multiple plasma heads (e.g., 910, 920, 930, 940, etc.) to perform a respective operation on the object (e.g., preparation of a surface, deposition of a layer, etc.). For example, one or more of the plasma heads (e.g., 910, 920, 930, 940, etc.) may prepare an object (e.g., object 220 alone, object 220 with the addition of one or more additional layers, etc.) for deposition of a layer using APP-CVD (e.g., in step 820 of FIG. 8). As another example, one or more of the plasma heads (e.g., 910, 920, 930, 940, etc.) may deposit a layer on an object (e.g., object 220 alone, object 220 with the addition of one or more additional layers, etc.) using APP-CVD (e.g., in process 100 of FIG. 1, in step 830 of FIG. 8, etc.).

System 900 may enable efficient manufacturing of a solar cell by forming an assembly line for automatically performing subsequent operations on an object. For example, object 220 may be accessed (e.g., after placement on component 950) and moved by component 950 toward plasma head 910 for preparation or cleaning (e.g., to form object 971). Object 971 may then be moved by component 950 toward plasma head 920 for deposition of a first layer (e.g., to form object 972), where the first layer may be a P-type silicon layer, an intrinsic layer, a N-type silicon layer, a conductive layer, a tunnel junction layer, etc. Object 972 may then be moved by component 950 toward plasma head 930 for deposition of a second layer (e.g., to form object 973), where the second layer may be a P-type silicon layer, an intrinsic layer, a N-type silicon layer, a conductive layer, a tunnel junction layer, etc. Object 973 may then be moved by component 950 toward plasma head 940 for deposition of a third layer (e.g., to form object 974), where the third layer may be a P-type silicon layer, an intrinsic layer, a N-type silicon layer, a conductive layer, a tunnel junction layer, etc. Object 974 may then be removed from system 900.

In one embodiment, object 974 may be a completed solar cell (e.g., 400, 500, 600, 700, etc.) or a nearly completed solar cell (e.g., solar cell 400 without second conductive layer 470, solar cell 400 before addition of adhesive layer 580 and second substrate 590 to form solar cell 500, etc.). In this manner, system 900 may be used to transform a very raw or unfinished object (e.g., 220 which consists of only substrate 410, substrate 410 with only first conductive layer 420, etc.) into a completed or nearly-completed solar cell.

System 900 may improve the efficiency and cost associated with solar cell production. For example, the object may be moved from one plasma head to another relatively quickly since the multiple plasma heads of system 900 may be located close to one another in one embodiment, thereby reducing the time required to perform the operations on the object (e.g., preparation of a surface, deposition of a layer, etc.). Additionally, system 900 may have a relatively small footprint, and therefore, may be housed in a smaller, less-expensive manufacturing facility.

Additionally, it should be appreciated that one or more of the multiple plasma heads (e.g., 910, 920, 930, 940, etc.) may be used in parallel to further improve the efficiency of system 900. For example, plasma head 910 may be used to prepare or clean a first object while plasma head 920 deposits a first layer on a second object.

Although FIG. 9 shows system 900 with four plasma heads (e.g., 910, 920, 930 and 940), it should be appreciated that system 900 may utilize a larger or smaller number of plasma heads in other embodiments. Further, although component 950 is depicted as a conveyor belt or similar type of movement mechanism, it should be appreciated that component 950 may be another type of mechanism capable of moving an object (e.g., a robot arm, etc.) in other embodiments.

FIG. 10 shows an exemplary flow of gas through system 900 in accordance with one embodiment of the present invention. As shown in FIG. 10, housing 1060 may enclose or partially enclose the multiple plasma heads (e.g., 910, 920, 930, 940, etc.) of system 900. Housing 1060 may also create inlet ports (e.g., 1072, 1074, etc.) and/or exhaust ports (e.g., 1051, 1052, 1053, 1058, 1059, etc.) for controlling the gas flow through system 900.

As shown in FIG. 10, gases (e.g., the first gas introduced in step 120 of FIG. 1, the second gas introduced in step 140 of FIG. 1, gas used to prepare a surface of an object in step 820 of FIG. 8, etc.) may enter plasma head 910 through gas line 1015 and exit housing 1060 through exhaust port 1051 (e.g., as depicted by arrow 1019). Gases (e.g., the first gas introduced in step 120 of FIG. 1, the second gas introduced in step 140 of FIG. 1, gas used to prepare a surface of an object in step 820 of FIG. 8, etc.) may enter plasma head 920 through gas line 1025 and exit housing 1060 through exhaust port 1051 (e.g., as depicted by arrow 1028) and/or exhaust port 1052 (e.g., as depicted by arrow 1029). Gases (e.g., the first gas introduced in step 120 of FIG. 1, the second gas introduced in step 140 of FIG. 1, gas used to prepare a surface of an object in step 820 of FIG. 8, etc.) may enter plasma head 930 through gas line 1035 and exit housing 1060 through exhaust port 1052 (e.g., as depicted by arrow 1038) and/or exhaust port 1053 (e.g., as depicted by arrow 1039). Gases (e.g., the first gas introduced in step 120 of FIG. 1, the second gas introduced in step 140 of FIG. 1, gas used to prepare a surface of an object in step 820 of FIG. 8, etc.) may enter plasma head 940 through gas line 1045 and exit housing 1060 through exhaust port 1053 (e.g., as depicted by arrow 1049).

Additionally, gases may flow on the sides of the plasma heads to reduce the ability of air or other contaminants from entering system 900. For example, gas (e.g., Argon) may flow into inlet port 1072 and exit through exhaust port 1058 (e.g., as depicted by arrow 1080). Additionally, gas (e.g., Argon) may flow into inlet port 1074 and exit through exhaust port 1059 (e.g., as depicted by arrow 1090).

In one embodiment, pressure differentials within system 900 may create the flow of gases depicted in FIG. 10. For example, the pressure within each of the plasma heads (e.g., 910, 920, 930, 940, etc.) may be higher than that outside the plasma heads within housing 1060 (e.g., in the areas corresponding to arrows 1019, 1028, 1029, 1038 and 1049), and the pressure outside the plasma heads within housing 1060 (e.g., in the areas corresponding to arrows 1019, 1028, 1029, 1038 and 1049) may be higher than atmospheric pressure (e.g., outside housing 1060). Therefore, gases from within each plasma head may flow out of housing 1060 thorough an exhaust port in housing 1060 (e.g., exhaust ports 1051, 1052, 1053, etc.).

Additionally, the gas flowing on the sides of the plasma heads (e.g., corresponding to arrows 1080 and 1090), may be injected at a higher pressure than that within housing 1060, where the pressure within housing 1060 is higher than atmospheric pressure outside housing 1060. As such, the gas will flow from the inlet ports (e.g., 1072 and 1074) through their respective exhaust ports (e.g., 1058 and 1059).

In one embodiment, the gas flow through system 900 as depicted in FIG. 10 may reduce contamination of a plasma head. For example, the gas flow from each exhaust port (e.g., 1051, 1052, 1053, 1058 and 1059) as depicted in FIG. 10 may reduce the ability of contaminants (e.g., air, other gas, dirt, other particulate matter, etc.) outside housing 1060 to enter housing 1060 and contaminate the plasma heads (e.g., 910, 920, 930, 940, etc.). As another example, the gas flow through housing 1060 as depicted in FIG. 10 may “flush” contaminants (e.g., air, other gas, dirt, other particulate matter, etc.) residing within housing 1060, thereby reducing the ability of contaminants (e.g., air, other gas, dirt, other particulate matter, etc.) within housing 1060 to contaminate the plasma heads (e.g., 910, 920, 930, 940, etc.).

As a further example, the gas flow through system 900 as depicted in FIG. 10 may reduce contamination of one plasma head from the exhaust gases produced by the remaining plasma heads. For example, the exhaust gases from plasma heads 920, 930 and 940 may be unable to flow toward or near plasma head 910, and therefore, the contamination of plasma head 910 from the exhaust gases from the other plasma heads (e.g., 920, 930 and 940) may be reduced.

One or more of the plasma heads (e.g., 910, 920, 930, 940, etc.) may be purged before use. For example, before preparing a surface (e.g., in step 820 of FIG. 8), depositing a layer (e.g., in step 150 of FIG. 1, in step 830 of FIG. 8, etc.) or performing some other function, gas (e.g., Argon) may be run through the plasma head to purge it. As another example, before igniting the plasma in a respective plasma head, gas (e.g., Argon) may be run through the plasma head to purge it. The purging of the plasma head may help flush out contaminants (e.g., air, other gas, dirt, other particulate matter, etc.) from the plasma head.

In one embodiment, a plasma head (e.g., 910, 920, 930, 940, etc.) need not be re-purged if it remains pressurized after the initial purge. Accordingly, solar cell production may be made more efficient using system 900 by pressuring one or more of the plasma heads (e.g., 910, 920, 930, 940, etc.) after the initial purge. In this manner, one or more solar cells may be produced using system 900 without re-purging a plasma head (e.g., 910, 920, 930, 940, etc.) in one embodiment, thereby improving efficiency and reducing cost.

FIG. 11 shows a flowchart of exemplary process 1100 for producing a Silicon gas in accordance with another embodiment of the present invention. As shown in FIG. 11, step 1110 involves converting sand to quartz. In one embodiment, sand may be heated at approximately 2000 degrees Celsius to produce quartz in step 1110.

Step 1120 involves grinding the quartz into quartz powder. The quartz powder is injected into a chamber in step 1130.

As shown in FIG. 11, step 1140 involves reacting the quartz powder with Hydrochloride (HCl) to create TrichloroSilane (TCS) gas. In one embodiment, the quartz powder is reacted with the Hydrochloride at 300 degrees Celsius.

Step 1150 involves filtering the TCS gas (e.g., created in step 1140) to create filtered TCS gas. The filtered TCS gas is purified in step 1160 to create purified TCS gas.

As shown in FIG. 11, the TCS gas (e.g., the purified TCS gas produced in step 1150) may be used to deposit a layer using APP-CVD (e.g., in step 150 of FIG. 1, in step 830 of FIG. 8, etc.). In this manner, the TCS gas (e.g., produced in step 1140,1150 or 1160) may be used as a processing gas to deposit a layer using APP-CVD (e.g., in accordance with process 100 of FIG. 1, process 800 of FIG. 8, etc.).

Alternatively, as shown in FIG. 11, a silicon ingot may be created from the TCS gas (e.g., the purified TCS gas produced in step 1150) in step 1180. Step 1190 involves cutting the silicon ingot into silicon wafers. In one embodiment, the silicon wafers may be used as a substrate (e.g., 410, etc.) for a solar cell (e.g., 400, 500, 600, 700, etc.). In this manner, the TCS gas (e.g., produced in step 1140, 1150 or 1160) may be used to produce a silicon substrate.

In the foregoing specification, embodiments of the invention have been described with reference to numerous specific details that may vary from implementation to implementation. Thus, the sole and exclusive indicator of what is, and is intended by the applicant to be, the invention is the set of claims that issue from this application, in the specific form in which such claims issue, including any subsequent correction. Hence, no limitation, element, property, feature, advantage, or attribute that is not expressly recited in a claim should limit the scope of such claim in any way. Accordingly, the specification and drawings are to be regarded in an illustrative rather than a restrictive sense.

What is claimed is:

1. A method for atmospheric pressure plasma chemical vapor deposition, said method comprising:
introducing a first gas into a chamber;
igniting a plasma inside said chamber using said first gas, wherein said igniting further comprises igniting said plasma at conditions comprising substantially atmospheric pressure;
introducing a second gas into said chamber, wherein said second gas comprises a constituent, and wherein said introducing said second gas further comprises introducing said second gas into said plasma along with said first gas into said chamber; and
depositing a first layer on an object within said chamber, wherein said first layer comprises said constituent, and wherein said depositing further comprises depositing said first layer using said plasma at substantially atmospheric pressure.

2. The method of claim 1, wherein said first gas is selected from a group consisting of argon, hydrogen and nitrogen.

3. The method of claim 1, wherein said object comprises a substrate selected from a group consisting of a silicon substrate, a glass substrate, a flexible substrate, a polymer substrate, and a stainless steel substrate.

4. The method of claim 1, wherein said object comprises a substrate with a second layer deposited thereon, and wherein said depositing said first layer further comprises depositing said first layer on said second layer.

5. The method of claim 1, wherein said first layer comprises a P-type silicon layer, wherein said second gas comprises a mixture of diborane and a processing gas.

6. The method of claim 1, wherein said first layer comprises an intrinsic layer, and wherein said second gas comprises a processing gas without a dopant.

7. The method of claim 1, wherein said first layer comprises a N-type silicon layer, and wherein said second gas comprises a mixture of phosphine and a processing gas.

8. The method of claim 1, wherein said first layer comprises a transparent conductive layer, wherein said second gas comprises a mixture of diethylzinc, oxygen and a third gas, and wherein said third gas comprises aluminum.

9. The method of claim 1, wherein said igniting further comprises igniting said plasma using a voltage selected from a group consisting of a voltage of approximately 1 kV and a voltage greater than 1 kV.

10. A method of producing a solar cell using atmospheric pressure plasma chemical vapor deposition, said method comprising:
accessing an object comprising a substrate with a first conductive layer disposed thereon;
depositing a plurality of layers on said object to form at least one P-N junction, wherein said depositing further comprises depositing said plurality of layers using at least one plasma ignited within at least one chamber at substantially atmospheric pressure, and wherein said plurality of layers comprise a P-type layer, an N-type layer, and an intrinsic layer disposed between said P-type layer and said N-type layer; and
disposing a second conductive layer on said plurality of layers to form said solar cell, and wherein said plurality of layers are operable to generate a potential difference between said first conductive layer and said second conductive layer when exposed to light energy.

11. The method of claim 10, wherein said depositing said plurality of layers further comprises:
introducing a first gas into said at least one chamber;
igniting said at least one plasma inside said at least one chamber using said first gas, wherein said igniting further comprises igniting said at least one plasma at substantially atmospheric pressure;
introducing a second gas into said at least one chamber, wherein said second gas comprises a constituent, and wherein said introducing said second gas further comprises introducing said second gas into said at least one plasma along with said first gas into said at least one chamber; and
depositing a first layer of said plurality of layers on said object, wherein said first layer comprises said constituent.

12. The method of claim 10, wherein said depositing said plurality of layers further comprises depositing said plurality of layers using a plurality of plasma heads.

13. The method of claim 12, wherein a first plasma head of said plurality of plasma heads is operable to deposit said P-type silicon layer using a mixture of diborane and a processing gas.

14. The method of claim 12, wherein a second plasma head of said plurality of plasma heads is operable to deposit said intrinsic layer using a processing gas without a dopant.

15. The method of claim 12, wherein a third plasma head of said plurality of plasma heads is operable to deposit said N-type silicon layer using a mixture of phosphine and a processing gas.

16. The method of claim 10 further comprising:
preparing a surface of said object to accept said plurality of layers using a plasma ignited at substantially atmospheric pressure.

17. The method of claim 10, wherein said plurality of layers comprise multiple P-N junctions.

18. The method of claim 10 further comprising:
disposing an adhesive layer on said second conductive layer; and
disposing a second substrate on said adhesive layer.

19. The method of claim 18, wherein said second substrate comprises glass, and wherein said solar cell is a photovoltaic solar cell window.

20. A system for producing a solar cell using atmospheric pressure plasma chemical vapor deposition, said system comprising:
a plurality of plasma heads comprising:
a first plasma head comprising a first chamber, wherein said first plasma head is operable to deposit a P-type silicon layer using a first plasma ignited within said first chamber at substantially atmospheric pressure;
a second plasma head coupled with said first plasma head and comprising a second chamber, wherein said second plasma head is operable to deposit an intrinsic layer using a second plasma ignited within said second chamber at substantially atmospheric pressure; and
a third plasma head coupled with said second plasma head and comprising a third chamber, wherein said third plasma head is operable to deposit a N-type silicon layer using a third plasma ignited within said third chamber at substantially atmospheric pressure; and
a component for moving an object to enable said plurality of plasma heads to deposit a plurality of layers on said object, wherein said object comprises a substrate with a first conductive layer disposed thereon, wherein said plurality of layers comprise a P-type layer, an N-type layer, and an intrinsic layer disposed between said P-type layer and said N-type layer, and wherein said plurality of layers are operable to generate a potential difference between said first conductive layer and a second conductive layer when exposed to light.

21. The system of claim 20, wherein said first plasma head is further operable to deposit said P-type silicon layer using a mixture of diborane and a processing gas.

22. The system of claim 20, wherein said second plasma head is further operable to deposit said intrinsic layer using a processing gas without a dopant.

23. The system of claim 20, wherein said third plasma head is further operable to deposit said N-type silicon layer using a mixture of phosphine and a processing gas.

24. The system of claim 20, wherein said plurality of plasma heads further comprises:
a fourth plasma head coupled with said first plasma head and comprising a fourth chamber, wherein said fourth plasma head is operable to prepare a surface of said object using a fourth plasma ignited within said fourth chamber at substantially atmospheric pressure, wherein said fourth plasma head is further operable to prepare said surface to accept said plurality of layers.

25. The system of claim 20, wherein said plurality of layers comprise multiple P-N junctions.
